(19) United States
(12) Patent Application Publication
(10) Pub. No.: US 2019/0013760 A1
(43) Pub. Date: Jan. 10, 2019

(54) DIRECT-CURRENT SENSOR, ALTERNATING-CURRENT SENSOR, AND INVERTER HAVING THE SAME

(71) Applicant: HITACHI AUTOMOTIVE SYSTEMS, LTD., Hitachinaka-shi, Ibaraki (JP)

(72) Inventors: Toshisada MITSUI, Hitachinaka-shi (JP); Hideki MIYAZAKI, Hitachinaka-shi (JP); Koichi YAHATA, Hitachinaka-shi (JP); Katsuhiro HOSHINO, Hitachinaka-shi (JP)

(73) Assignee: HITACHI AUTOMOTIVE SYSTEMS, LTD., Hitachinaka-shi, Ibaraki (JP)

(21) Appl. No.: 16/067,418

(22) PCT Filed: Dec. 16, 2016
(86) PCT No.: PCT/JP2016/087465

§ 371 Date: Jun. 29, 2018

(30) Foreign Application Priority Data
Jan. 18, 2016 (JP) 2016-006756

(51) Int. Cl. H02P 27/06; B60L 11/18; G01R 31/28; H02M 7/537

(52) U.S. Cl. CPC H02P 27/06; B60L 11/1803; H02P 2201/03; H02M 7/537; G01R 31/2829

(57) ABSTRACT

The present invention is devised to allow accurate determination on quality of a current sensor, and provide a current sensor reduced in size and cost and an inverter having the current sensor.

A direct-current sensor 380 detects direct currents supplied to a plurality of inverters 300 and 301 for driving an alternating-current motor 200 in which winding wires of a stator are independent from each other in individual phases and a voltage is individually applied to the independent winding wires. The plurality of inverters has a P connecting wire 150 connecting P buses and an N connecting wire 160 connecting N buses. The direct-current sensor 380 has a core surrounding the P connecting wire and the N connecting wire to detect the currents flowing into and out of the P bus and the N bus. This makes it possible to employ a small-capacity current sensor, improve the sensor accuracy, and allow accurate determination on the quality of the current sensor.

### TECHNICAL FIELD

The present invention relates to a direct-current sensor and an alternating-current sensor that detect a current supplied to a motor used in a hybrid electric vehicle (HEV) or electric vehicle (EV), and an inverter having these sensors. The present invention relates more particularly to a direct-current sensor, an alternating-current sensor, and an inverter that are best suited to an electric motor drive device that drives a permanent magnet synchronous motor in which armature winding wires of a stator of the motor are independent in individual phases.

### BACKGROUND ART

Hybrid electric vehicles and electric vehicles are limited in battery capacity. A voltage for driving a motor has a limited value in accordance with the number of batteries connected in series and a charging state. The motor for running a hybrid electric vehicle or electric vehicle is mainly a permanent magnet synchronous motor, and specifically, an interior permanent magnet motor (IPM) that satisfies the demand for low speed, high torque, and a wider rotation speed region is used.

In the permanent magnet synchronous motor, a magnet flux of the permanent magnet attached to the rotor is interlinked with the armature winding wires to induce a voltage in the armature winding wires. With increase in rotation speed, the induced voltage becomes higher. Thus, a motor drive device needs to control the current to the motor to generate necessary torque while suppressing the induced voltage. Accordingly, the operation of the motor is limited by a direct-current voltage of the battery.

To further increase an AC voltage to the motor with a limitation on the direct-current voltage of the battery, there is known a drive device for an open-winding motor in which the winding wires of a stator of the motor in individual phases are independent from each other. The drive device for an open-winding motor allows increase in output capacity.

There is also known a method for determining quality of current sensors for use in a motor drive device by the sum of detection values of three AC currents (see PTL 1). This method is based on Kirchhoff's law, that is, the law under which the sum of currents flowing into and out of a circuit is zero.

### CITATION LIST

### Patent Literature

PTL 1: JP H9-23501 A

### SUMMARY OF INVENTION

### Technical Problem

The drive device for an open-winding motor will be described with reference to a wiring diagram of an electric motor drive device according to a related technique described in FIG. 1. FIG. 1 is a diagram for describing a diagnostic principle for current sensors in the electric motor drive device.

In the electric motor drive device, an AC current flows from a three-phase inverter 300 into a motor 200, and then flows into another three-phase inverter 301. In addition, the three-phase inverter 300 and the three-phase inverter 301 exchange bus current via connecting wires 340, 360, 350, and 370 connecting a P bus and an N bus. Therefore, quality of the current sensors cannot be determined only with detection values Iu, Iv, and Iw of the three AC currents. To capture the sum of the currents flowing into and out of the circuit, it is necessary to detect the currents flowing into and out of the P bus and the N bus as well as the three AC currents.

A current to a P bus connecting wire 340 is designated as IdL1, a current to the bus connecting wire 360 as IdR1, a current to the N bus connecting wire 350 as IdL2, and a current to the N bus connecting wire 370 as IdR2.

From the foregoing, the following Mathematical Formulas (1) and (2) hold and thus (Iu+Iv+Iw) is not basically zero.

[Mathematical Formula 1]

Iu+Iv+Iw+IdL1+IdL2=0 (1)

[Mathematical Formula 2]

Iu+Iv+Iw+IdR1+IdR2=0 (2)

All the currents described in Mathematical Formula (1) or (2) are detected and the sum of them is determined. When the sum of the currents falls within a threshold taking sensor accuracy and detection timing gaps into account, all the current sensors are judged as good. When the sum of currents exceeds the threshold, any of the current sensors is judged as not good. The 0-axis current of a motor is generally defined by Mathematical Formula (3), which is combined with Mathematical Formulas (1) and (2) into Mathematical Formula (4) as follows:

$$\begin{matrix}[ Mathematical Formula 3 ] & \\ {I}_{z} = \frac{1}{\sqrt{3}} \cdot ( Iu + Iv + Iw ) & ( 3 ) \\ [ Mathematical Formula 4 ] & \\ - \sqrt{3} \cdot {I}_{z} = IdL 1 + IdL 2 = IdR 1 + IdR 2 & ( 4 )\end{matrix}$$

As a result, the 0-axis current of the motor can be obtained by calculating (Iu+Iv+Iw) or by detecting (IdL1+IdL2) or (IdR1+IdR2). The following description is based on a set of currents (IdL1+IdL2).

An object of the present invention is to determine accurately the quality of current sensors. The current IdL1 includes part of the motor 0-axis current and a current derived from the direct-current power source. The current IdL2 includes the remainder of the motor 0-axis current and a current of the opposite polarity derived from the direct-current power source. This can be expressed by Mathematical Formulas (5), (6), and (7) as follows:

[Mathematical Formula 5]

IdL1=IdL+A (5)

[Mathematical Formula 6]

IdL2=−IdL+B (6)

[Mathematical Formula 7]

where

−\sqrt{3}·I₂=A+B (7)

To detect the two currents, it is necessary to prepare two current sensors with relatively large capacity. The accuracy of a current sensor is specified by ratio, and becomes lowered at the detection of a large current. Accordingly, the accuracy of determination on the quality of current sensors becomes reduced.

Another object of the present invention is size and cost. The number of current sensors is preferably small to make the electric motor drive device compact in size. In addition, the number of current sensor is preferably small from the viewpoint of cost as well.

### Solution to Problem

A direct-current sensor according to the present invention is a direct-current sensor that detects direct currents supplied to a plurality of inverters for driving an alternating-current motor in which winding wires of a stator are independent from each other in individual phases and a voltage is individually applied to the independent winding wires. The plurality of inverters has a P connecting wire connecting P buses for the plurality of inverters and an N connecting wire connecting N buses for the plurality of inverters. The direct-current sensor has a core surrounding the P connecting wire and the N connecting wire.

According to the present invention, one current sensor detects a set of currents (IdL1 and IdL2), which makes it possible to cancel out the current derived from the direct-current power source and obtain only the 0-axis current.

As another means, detecting (IdL1 and IdL2) is equivalent to detecting (Iu+Iv+Iw) according to Mathematical Formulas (3) and (4). Therefore, one current sensor may be configured to detect collectively the three AC currents.

### Advantageous Effects of Invention

According to the present invention, the capacity of the current sensor only needs to match the 0-axis current, which makes it possible to detect accurately the direct currents for driving the alternating-current motor. Therefore, it is possible to accurately determine the quality of the current sensors. In addition, two current sensors can be reduced to one, which makes the electric motor drive device compact in size and allows cost reduction. Another advantageous effect of the present invention is to detect accurately the 0-axis current and control accurately the 0-axis current.

### BRIEF DESCRIPTION OF DRAWINGS

FIG. 1 is a wiring diagram of a conventional electric motor drive device.

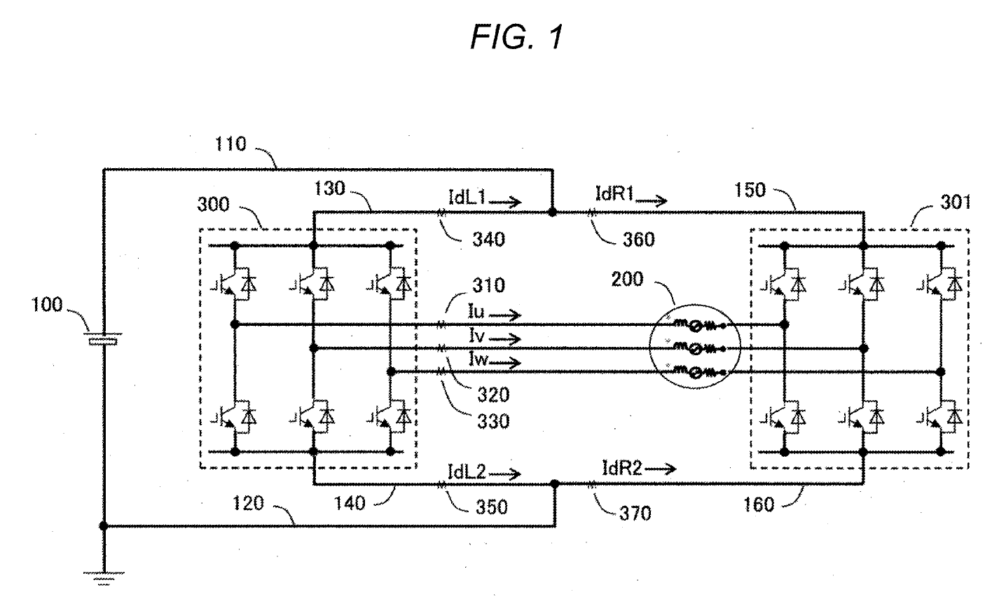

FIG. 2 is a wiring diagram of an electric motor drive device according to Example 1 of the present invention.

FIG. 3 is a wiring diagram of an electric motor drive device according to Example 2 of the present invention.

FIG. 4 is a wiring diagram of an electric motor drive device according to Example 3 of the present invention.

FIG. 5 is a perspective view of a specific example of a current sensor.

### DESCRIPTION OF EMBODIMENTS

### EXAMPLE 1

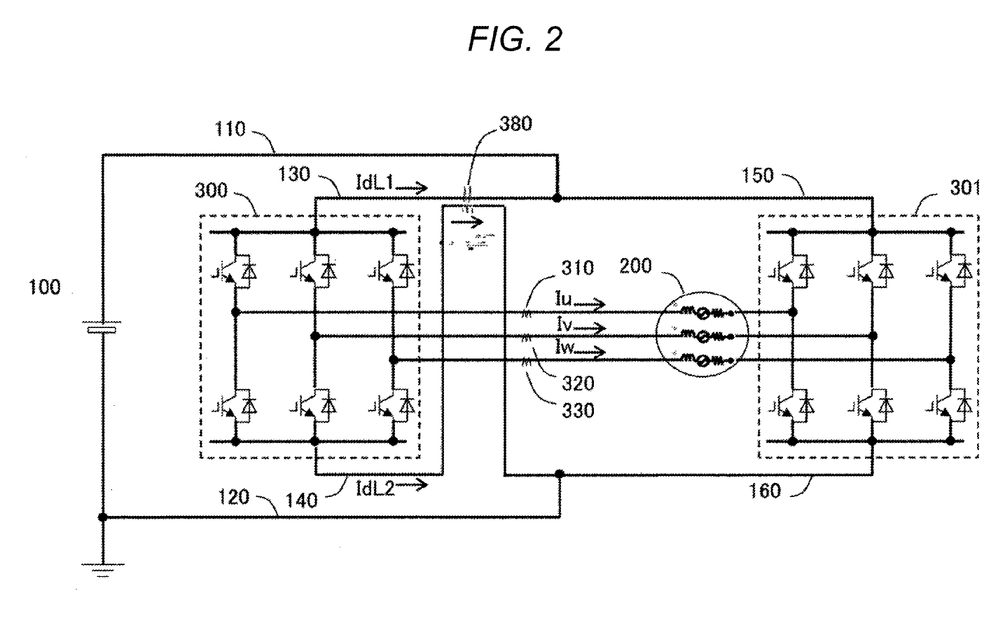

(System configuration) FIG. 2 is a wiring diagram of an electric motor drive device according to Example 1 of the present invention, which describes the current detection positions at which Kirchhoff's law holds in Example 1.

An electric motor drive device according to Example 1 is a drive device for an open-winding motor, which has a battery 100, an open-winding motor 200, and two three-phase inverters 300 and 301.

The battery 100 is connected to P bus connecting wires 130 and 150 via a plus direct-current power cable 110. The battery 100 is also connected to N bus connecting wires 140 and 160 via a minus direct-current power cable 120. The P bus connecting wire 130 and the N bus connecting wire 140 connect to a P bus and an N bus of the three-phase inverter 300. The P bus connecting wire 150 and the N bus connecting wire 160 connect to a P bus and an N bus of the three-phase inverter 301. With the foregoing connections, the battery 100 and the three-phase inverters 300 and 301 exchange direct-current power.

The three-phase inverter 300 and the open-winding motor (alternating-current motor) 200 connect to each other to exchange AC power. Similarly, the three-phase inverter 301 and the open-winding motor 200 connect to each other to exchange AC power. In this manner, the three-phase inverters 300 and 301 include switching circuit units that convert a direct current into an alternating current.

The open-winding motor 200 externally exchanges mechanical output via a mechanical output shaft not illustrated. The open-winding motor 200 also includes a rotation angle sensor not illustrated. Three AC sensors (alternating-current sensors) 310, 320, and 330 are provided between the three-phase inverter 300 and the open-winding motor 200 to detect AC currents (Iu, Iv, and Iw) of respective phases.

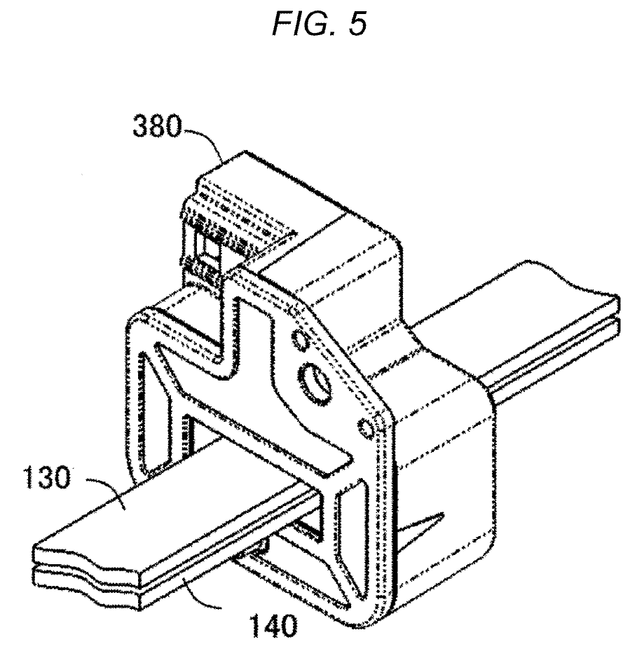

The P bus connecting wire 130 and the N bus connecting wire 140 are partly arranged in proximity to each other, and a DC sensor (direct-current sensor) 380 detects collectively currents (IdL1 and IdL2) flowing to the P bus connecting wire 130 and the N bus connecting wire 140. Specifically, as illustrated in FIG. 5, the P bus connecting wire 130 and the N bus connecting wire 150 are arranged to pass through the core in the DC sensor 380 to obtain the sum of IdL1 and IdL2.

(Principle)

The four sensors 310, 320, 330, and 380 can detect the sum of values of five currents flowing from the three-phase inverter 300. Mathematical Formula (1) can be used under Kirchhoff's law. The value of Iu+Iv+Iw+(IdL1+IdL2) is evaluated by a threshold taking errors in the current sensors and detection errors resulting from detection timing gaps into account. When the absolute value of the sum of the five currents falls below the threshold, all the current sensors are judged as good. When the absolute value of the sum of the five currents exceeds the threshold, any of the current sensors is judged as not good.

The electric motor drive device illustrated in FIG. 2 has the three-phase inverters 300 and 301 and the DC sensor 380 to drive the alternating-current motor 200. The electric motor drive device has a diagnosis unit that diagnoses a failure of the DC sensor 380 and/or the AC sensor 310, 320, and 330 based on output information from the DC sensor and output signals from the AC sensors. The three-phase inverters 300 and 301 include switching circuit units that convert a direct current into an alternating current, and serve as control units that control the switching circuit units to suppress an error between the 0-phase current in the P bus connecting wire 130 and the 0-phase current in the N bus connecting wire 140 based on the output information from the DC sensor 380.

In this configuration, the currents (IdL1 and IdL2) are collectively detected, and the current derived from the battery (direct-current power source) is canceled out as described above. This makes it possible to use a current sensor with a capacity suitable to √3 times the 0-axis current, without the need to use a larger-capacity current sensor allowing for the current derived from the battery (direct-current power source). Accordingly, the detection error between the currents (IdL1+IdL2) can be reduced as compared to that in the case where two current sensors detect separately the two currents. This makes it possible to decrease the threshold and improve the accuracy of determination on the quality of the current sensors. In addition, two current sensors for measuring direct currents can be reduced to one, which makes the drive device compact in size and allows cost reduction.

The 0-axis current can be detected by multiplying the currents (IdL1+IdL2) by a coefficient. When the three AC currents lu, lv, and lw are separately detected and the 0-axis current is determined from the sum of them, the accuracy of the detection becomes lowered with errors in the three current sensors and errors resulting from gaps in current detection timing. In the configuration of the present invention, an error in the 0-axis current can be controlled by an error in one current sensor to improve the accuracy of the 0-axis current. The 0-axis current can be accurately controlled by using this detection value.

### EXAMPLE 2

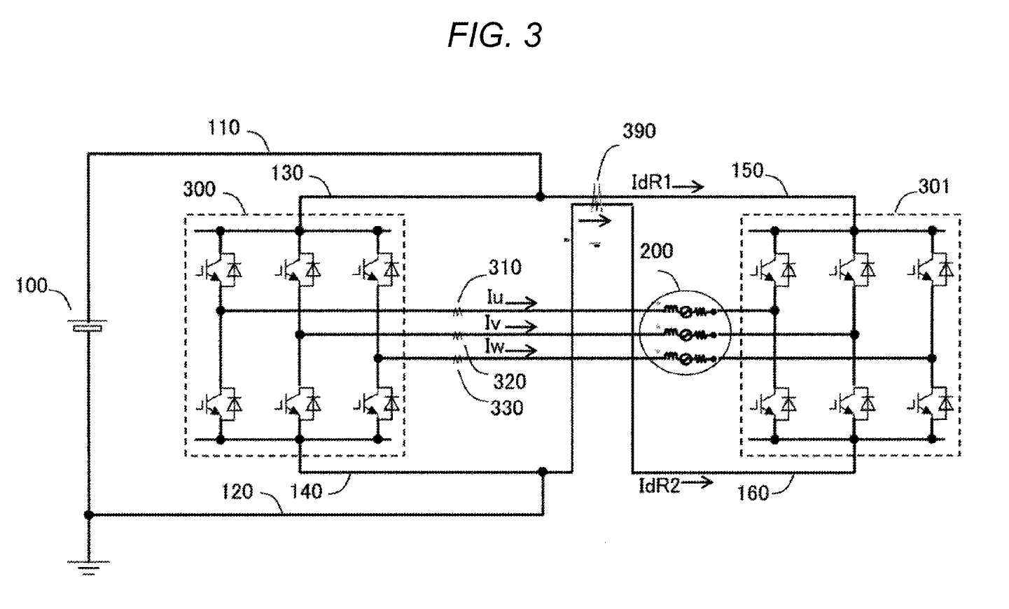

FIG. 3 is a wiring diagram of an electric motor drive device according to Example 2 of the present invention. Example 2 is different from Example 1 in that, without the DC sensor 380, the P bus connecting wire 150 and the N bus connecting wire 160 are partly arranged in proximity to each other so that a DC sensor 390 detects collectively currents (IdR1 and IdR2) flowing to the P bus connecting wire 150 and the N bus connecting wire 160. The DC sensor 390 has a core surrounding the P bus connecting wire 150 and the N bus connecting wire 160.

The open-winding motor 200 and the three-phase inverter 301 are handled as one circuit that detects the sum of five currents flowing into the circuit, where Kirchhoff's law can be used as well. As for other components, Example 2 is identical to Example 1 and thus detailed descriptions thereof will be omitted.

The electric motor drive device illustrated in FIG. 3 has the three-phase inverters 300, 301, and the DC sensor 390 to drive the alternating-current motor 200. The electric motor drive device can diagnose a failure of the DC sensor 395 and/or the AC sensors 310, 320, and 330 based on output information from the DC sensor 390 and output signals from the AC sensors 310, 320, and 330 of respective phases. The three-phase inverters 300 and 301 include switching circuit units that convert a direct current into an alternating current, and control the switching circuit units to suppress an error in the 0-phase current based on the output information from the DC sensor 390.

### EXAMPLE 3

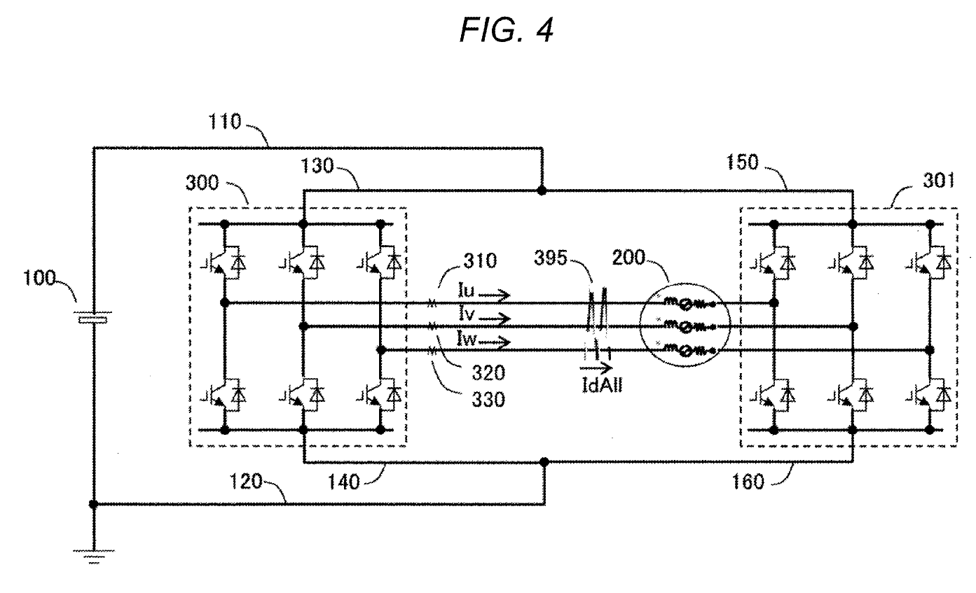

FIG. 4 is a wiring diagram of an electric motor drive device according to Example 3 of the present invention. Example 3 is different from Example 1 in that, without the DC sensor 380, an AC sensor 395 detects collectively the three AC values instead. Detection value (IdA11) is equivalent to (IdL1+IdL2). As for other components, Example 3 is identical to Example 1 and thus detailed descriptions thereof will be omitted. The AC sensor 395 has a core surrounding all three alternating-current wires of respective phases flowing currents in the alternating-current motor 200.

The electric motor drive device illustrated in FIG. 4 has the three-phase inverters 300, 301, and the AC sensor 395 to drive the alternating-current motor 200. The electric motor drive device can diagnose a failure of the AC sensor 395 and/or the AC sensors 310, 320, and 330 based on output information from the AC sensor 395 and output signals from the AC sensors 310, 320, and 330 of respective phases. The three-phase inverters 300 and 301 include switching circuit units that convert a direct current into an alternating current, and control the switching circuit units to suppress an error in the 0-phase current based on the output information from the AC sensor 395.

Embodiments of the present invention have been described in detail so far. However, the present invention is not limited to the foregoing embodiments but allows various design changes without deviating from the spirit of the present invention described in the claims. For example, the foregoing embodiments are described in detail for easy comprehension of the present invention and are not necessarily limited to the ones including all the components described above. In addition, some of components of an embodiment can be replaced with components of another embodiment, and components of an embodiment can be added to components of another embodiment. Some of components of the embodiments can be added, deleted, and replaced by other components.

### REFERENCE SIGNS LIST

100 battery (direct-current power source)
110 plus direct-current power cable
120 minus direct-current power cable
130, 150 P bus connecting wire (P connecting wire)
140, 160 N bus connecting wire (N connecting wire)
200 open-winding motor (alternating-current motor)
300, 301 three-phase inverter
310, 320, 330 AC sensors of U, V, and W phases
340, 360 current sensor detecting a current flowing into and out of P bus
350, 370 current sensor detecting a current flowing into and out of N bus
380, 390 current sensor detecting collectively currents flowing into and out of P bus and N bus
395 current sensor detecting collectively AC currents

1. A direct-current sensor that detects direct currents supplied to a plurality of inverters for driving an alternating-current motor in which winding wires of a stator are independent from each other in individual phases and a voltage is individually applied to the independent winding wires, wherein
the plurality of inverters has a P connecting wire connecting P buses for the plurality of inverters and an N connecting wire connecting N buses for the plurality of inverters, and
the direct-current sensor has a core surrounding the P connecting wire and the N connecting wire.

2. The direct-current sensor according to claim 1, outputting information including 0-phase current of the P connecting wire and 0-phase current of the N connecting wire.

3. An inverter with the direct-current sensor according to claim 1, comprising:
an alternating-current sensor that detects alternating currents flowing into the individual winding wires; and
a diagnosis unit that diagnoses a failure of the direct-current sensor and/or the alternating-current sensor based on output information from the direct-current sensor and an output signal from the alternating-current sensor.

4. An inverter with the direct-current sensor according to claim 2, comprising:
a switching circuit unit that converts the direct current into the alternating current; and
a control unit that controls the switching circuit unit to suppress the 0-phase currents based on output information from the direct-current sensor.

5. An alternating-current sensor that detects alternating currents flowing to respective phases of an alternating-current motor in which winding wires of a stator are independent from each other in individual phases and a voltage is individually applied to the independent winding wires, wherein
the alternating-current sensor has a core that surrounds all alternating-current wires flowing currents to the respective phases of the alternating-current motor.

6. An inverter with the alternating-current sensor according to claim 5, comprising:
a plurality of alternating-current sensors of respective phases that surrounds the individual alternating-current wires; and
a diagnosis unit that diagnoses a failure of the alternating-current sensor and/or the alternating-current sensors of the respective phases based on output information from the alternating-current sensor and output signals from the alternating-current sensor of the respective phases.

7. An inverter with the alternating-current sensor according to claim 5, comprising:
a switching circuit unit that converts the direct current into the alternating current; and
a control unit that controls the switching circuit unit to suppress the 0-phase currents based on output information from the alternating-current sensor.
